(19) United States
(12) Patent Application Publication
(10) Pub. No.: US 2012/0097234 A1
(43) Pub. Date: Apr. 26, 2012

(54) Using Diffusion Barrier Layer for CuZnSn(S,Se) Thin Film Solar Cell

(75) Inventors: Nestor A. Bojarczuk, Poughkeepsie, NY (US); Supratik Guha, Chappaqua, NY (US); Byungha Shin, White Plains, NY (US); Kejia Wang, Fishkill, NY (US)

(73) Assignee: International Business Machines Corporation, Armonk, NY (US)

(21) Appl. No.: 12/911,877

(22) Filed: Oct. 26, 2010

(51) Int. Cl. H01L 31/0224

(52) U.S. Cl. 136/256; 438/68; 257/E31.126

(57) ABSTRACT

Techniques for fabricating thin film solar cells, such as CuZnSn(S,Se) (CZTSSe) solar cells are provided. In one aspect, a method of fabricating a solar cell is provided that includes the following steps. A substrate is provided. The substrate is coated with a molybdenum (Mo) layer. A stress-relief layer is deposited on the Mo layer. The stress-relief layer is coated with a diffusion barrier. Absorber layer constituent components are deposited on the diffusion barrier, wherein the constituent components comprise one or more of sulfur (S) and selenium (Se). The constituent components are annealed to form an absorber layer, wherein the stress-relief layer relieves thermal stress imposed on the absorber layer, and wherein the diffusion barrier blocks diffusion of the one or more of S and Se into the Mo layer. A buffer layer is formed on the absorber layer. A transparent conductive electrode is formed on the buffer layer.

### FIELD OF THE INVENTION

The present invention relates to solar cells and more particularly, to techniques for CuZnSn(S,Se) (CZTSSe) thin film solar cell fabrication.

### BACKGROUND OF THE INVENTION

One of the major absorbing materials used as an absorbing layer in thin film solar cells is Cu₂InGa(S,Se)₄ (CIGS). However the scarcity of indium (In) and gallium (Ga) in CIGS poses a serious limitation in expanding CIGS to a wider usage. Recently, CuZnSn(S,Se) (CZTSSe) has been drawing a lot of attention due to its potential to replace CIGS. The common practice is to simply replace a CIGS layer within the complete stack of a solar cell device with a CZTSSe layer. However, the maximum quantum efficiency achieved by CZTS Se-based solar cells is much lower than that of CIGS-based solar cells, suggesting that a lot of modifications in the final device structure are necessary.

The substrate most commonly used for thin film solar cells (including CZTSSe) is a molybdenum (Mo)-coated soda lime glass (SLG) substrate. One important device fabrication step of a CZTSSe thin film solar cell is high temperature annealing (typically above 500 degrees Celsius (° C.)) under a sulfur (S) and/or selenium (Se) ambient to recrystallize the CZTSSe into a larger grain structure. It has been found, however, that during this annealing step, an undesirable reaction typically occurs between the ambient and the Mo which negatively affects device performance. Further, mechanical failure (i.e., delamination) of the CZTSSe film often occurs with conventional processes, especially when the CZTSSe film thickness is increased.

Therefore, fabrication techniques that prevent the above-described problems associated with use of a CZTSSe absorber layer for solar cells would be desirable.

### SUMMARY OF THE INVENTION

The present invention provides techniques for fabricating thin film solar cells, such as CuZnSn(S,Se) (CZTSSe) solar cells. In one aspect of the invention, a method of fabricating a solar cell is provided. The method includes the following steps. A substrate is provided. The substrate is coated with a molybdenum (Mo) layer. A stress-relief layer is deposited on the Mo layer. The stress-relief layer is coated with a diffusion barrier. Absorber layer constituent components are deposited on the diffusion barrier, wherein the constituent components comprise one or more of sulfur (S) and selenium (Se). The constituent components are annealed to form an absorber layer on the diffusion barrier, wherein the stress-relief layer relieves thermal stress imposed on the absorber layer by the annealing step, and wherein the diffusion barrier blocks diffusion of the one or more of S and Se into the Mo layer during the annealing step. A buffer layer is formed on the absorber layer. A transparent conductive electrode is formed on the buffer layer. The absorber layer can include CuZnSn(S,Se).

In another aspect of the invention, a solar cell is provided. The solar cell includes a substrate; a Mo layer coating the substrate; a stress-relief layer disposed on the Mo layer; a diffusion barrier coating the stress-relief layer; an absorber layer formed on the diffusion barrier; a buffer layer formed on the absorber layer; and a transparent conductive electrode formed on the buffer layer. The absorber layer can include CuZnSn(S,Se).

A more complete understanding of the present invention, as well as further features and advantages of the present invention, will be obtained by reference to the following detailed description and drawings.

### BRIEF DESCRIPTION OF THE DRAWINGS

FIG. 1 is a cross-sectional diagram illustrating a molybdenum (Mo)-coated soda-lime glass substrate according to an embodiment of the present invention;

FIG. 2 is a cross-sectional diagram illustrating a stress-relief layer and a diffusion barrier having been deposited on the Mo-coated substrate according to an embodiment of the present invention;

FIG. 3 is a cross-sectional diagram illustrating absorber layer constituent components having been deposited on the diffusion barrier according to an embodiment of the present invention;

FIG. 4 is a cross-sectional diagram illustrating a CuZnSn(S,Se) (CZTSSe) absorber layer having been formed from the constituent components on the Mo-coated substrate according to an embodiment of the present invention;

FIG. 5 is a cross-sectional diagram illustrating a buffer layer having been formed on the CZTSSe absorber layer according to an embodiment of the present invention;

FIG. 6 is a cross-sectional diagram illustrating a thin layer of intrinsic zinc oxide (ZnO) having been deposited on the buffer layer according to an embodiment of the present invention;

FIG. 7 is a cross-sectional diagram illustrating a transparent conductive oxide layer having been deposited on the intrinsic ZnO layer wherein the intrinsic ZnO layer and the transparent conductive oxide layer form a transparent conductive electrode according to an embodiment of the present invention;

FIG. 8 is a cross-sectional diagram illustrating a metal grid electrode having been formed on the transparent conductive electrode according to an embodiment of the present invention;

FIG. 9 is a cross-sectional diagram illustrating the structure having been divided into a number of isolated substructures according to an embodiment of the present invention;

FIG. 10 is a cross-sectional transmission electron microscopy (TEM) image of a CZTSSe layer-Mo interface showing the formation of a Mo(Cu,S) layer and the inhomogenous grains of CZTSSe near the interface according to an embodiment of the present invention;

FIG. 11A is a scanning electron microscope (SEM) image of a solar cell fabricated using the present techniques having a 3 nanometer (nm) thick diffusion barrier according to an embodiment of the present invention;

FIG. 11B is an SEM image of a solar cell fabricated using the present techniques having a 10 nm thick diffusion barrier according to an embodiment of the present invention;

FIG. 12A is a graph illustrating temperature dependence of series resistance for a solar cell having no diffusion barrier according to an embodiment of the present invention;

FIG. 12B is a graph illustrating temperature dependence of series resistance for a solar cell with a 3 nm thick diffusion barrier according to an embodiment of the present invention; and

FIG. 12C is a graph illustrating temperature dependence of series resistance for a solar cell with a 10 nm thick diffusion barrier according to an embodiment of the present invention.

### DETAILED DESCRIPTION OF PREFERRED EMBODIMENTS

The techniques provided herein solve the problems associated with CuZnSn(S,Se) (CZTSSe) thin film solar cell fabrication. As highlighted above, CZTSSe solar cells commonly employ a molybdenum (Mo)-coated soda lime glass (SLG) substrate and one important device fabrication step of a CZTSSe solar cell is high temperature annealing under a sulfur (S) and/or selenium (Se) ambient to recrystallize the CZTSSe into a larger grain structure. During this annealing step, the S and/or Se has been shown to react very aggressively with the underlying Mo layer to form (MoS)x and/or (MoSe)x between the CZTSSe absorber layer and the Mo-coated substrate. It has also been found during research of the present techniques that while the (MoS)x and/or (MoSe)x forms, copper (Cu) from the CZTSSe also diffuses into the (MoS)x and/or (MoSe)x.

The formation of (MoS)x and/or (MoSe)x between the CZTSSe absorber layer and the Mo-coated substrate can cause potential problems. First, (MoS)x and (MoSe)x pose a barrier height for the transport of charged carriers resulting in high series resistance that greatly deteriorates quantum efficiency of the final solar cell. Second, the diffusion of Cu from the CZTSSe layer to (MoS)x and/or (MoSe)x can disturb the composition of the CZTSSe near the CZTSSe-Mo interface, which can in turn cause phase separation.

Another problem associated with the high temperature annealing step is the often-observed mechanical failure of the CZTSSe (i.e., delamination of the CZTSSe layer from the Mo-coated substrate), especially when thick CZTSSe films are involved. This is due to a rather substantial difference in thermal expansion coefficient between the CZTSSe layer and the soda lime glass substrate. During annealing, CZTSSe is in compressive strain due to the thermal mismatch. When the stored strain energy exceeds the interfacial energy between the CZTSSe and the (MoS)x and/or (MoSe)x/Mo layer, the CZTSSe film delaminates. In order to ensure the maximum light absorption, a CZTSSe layer having a thickness of at least a couple of micrometers is required. However, the total strain energy stored in the CZTSSe layer scales with the layer thickness thereby preventing the formation of mechanically stable CZTSSe layers with an optimal thickness.

All of the above-described problems associated with conventional CZTSSe thin film solar cell fabrication are addressed and solved by the present techniques. FIGS. 1-9, for example, are cross-sectional diagrams illustrating an exemplary methodology for fabricating a (e.g., CZTSSe) solar cell. To begin the process, a substrate 102 is provided. See FIG. 1. A suitable substrate includes, but is not limited to, a soda-lime glass substrate. According to an exemplary embodiment, substrate 102 is from about 1 millimeters (mm) to about 3 mm thick. Next, as shown in FIG. 1, substrate 102 is coated with a Mo layer 104. According to an exemplary embodiment, Mo layer 104 is deposited onto substrate 102 by sputtering to a thickness of from about 600 nanometers (nm) to about 1 micrometer (μm). Substrate 102 and Mo layer 104 will also be referred to hereinas a Mo-coated substrate.

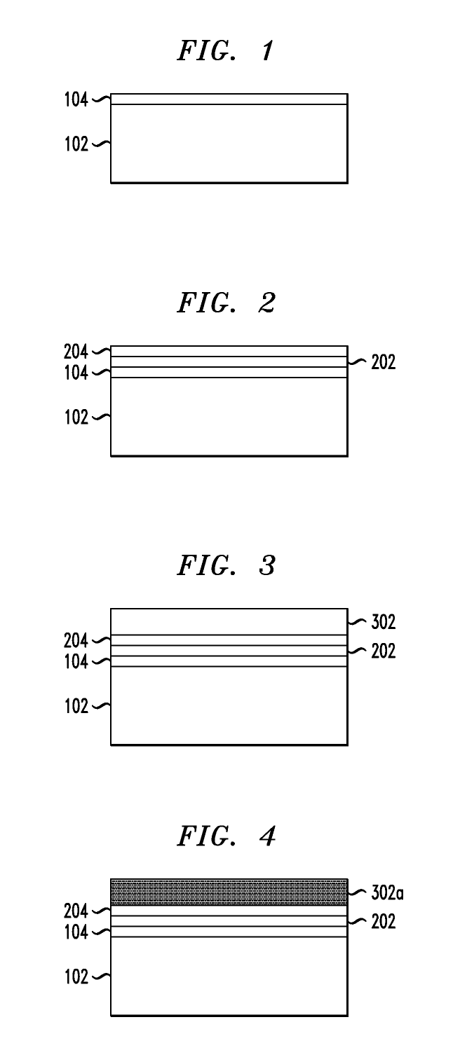

A stress-relief layer 202 is then deposited on the Mo-coated substrate (i.e., on the molybdenum layer). See FIG. 2. As highlighted above, a problem associated with high temperature annealing (to be performed later in the process) is a mechanical failure (i.e., delamination) of the absorber layer (in this case a CZTSSe layer) due to a substantial difference in thermal expansion coefficients between the CZTSSe and the soda-lime glass substrate. Advantageously, it has been found by way of the present techniques that the use of stress-relief layer 202 between the CZTSSe absorber layer (to be formed later in the process) and Mo-coated substrate effectively serves to relieve the thermal stress imposed on the CZTSSe absorber layer by undergoing plastic deformation during the high temperature annealing.

According to an exemplary embodiment, stress-relief layer 202 is made up of a soft metal, such as aluminum (Al), Cu and/or silver (Ag) and is deposited on the Mo-coated substrate using a deposition technique such as thermal evaporation or sputtering, to a thickness of from about 50 nm to about 1 μm.

As shown in FIG. 2, stress-relief layer 202 is then coated with a diffusion barrier 204. As highlighted above, during the above-mentioned high-temperature annealing step, the S and/or Se constituent components of the CZTSSe absorber layer can react very aggressively with the underlying Mo layer to form (MoS)x and/or (MoSe)x, while at the same time the Cu component of the layer can also diffuse into that (MoS)x and/or (MoSe)x. Both of these effects are undesirable. As described above, (MoS)x and/or (MoSe)x acts as a barrier for carrier transport and diffusion of Cu from CZTSSe disturbs the CZTSSe composition. Advantageously, it has been found by way of the present techniques that the use of a diffusion barrier between the CZTSSe absorber layer (to be formed later in the process) and the Mo-coated substrate can serve to effectively prevent the formation of the (MoS)x and/or (MoSe)x by blocking diffusion of the Cu, S and/or Se into the Mo.

According to an exemplary embodiment, diffusion barrier 204 is made up of titanium nitride (TiN), tantalum nitride (TaN) and/or tantalum nitride silicide (TaNSi) and is coated on stress-relief layer 202 using a deposition technique such as thermal evaporation with nitrogen plasma, sputtering, atomic layer deposition (ALD), or chemical vapor deposition (CVD), to a thickness of from about 3 nm to about 50 nm.

An absorber layer is then formed on diffusion barrier 204. In this example, the absorber layer includes CuZnSn(S/Se) and the constituent components of the absorber layer are Cu, zinc (Zn), tin (Sn) and S and/or Se. As shown in FIG. 3, the constituent components of the absorber layer are deposited on diffusion barrier 204, wherein the deposited constituent components are represented generically by box 302.

According to an exemplary embodiment, the absorber layer constituent components are deposited on diffusion barrier 204 using thermal evaporation, a solution process, electroplating or sputtering. Each of these deposition processes are known to those of skill in the art and thus are not described further herein. The constituent components can be provided in single element form, such as pure Cu, Zn, Sn, S and Se, or as compounds such as copper sulfide (CuS), zinc sulfide (ZnS), tin sulfide (SnS), copper selenide (CuSe), zinc selenide (ZnSe), tin selenide (SnSe) and/or Cu₂ZnSnₓSe₄₋ₓ.

Once the constituent components have been deposited, the components are annealed in the presence of S and/or Se to form CZTSSe absorber layer 302a on diffusion barrier 204. See FIG. 4. The use of a S and/or Se ambient during the anneal is dependent on whether or not S and/or Se are already present in the constituent components. For example, depositing CuS, ZnS and SnS would eliminate the need for an S ambient (although Se could in this case be provided in the ambient). On the other hand, Cu, Zn and Sn could be deposited followed by the anneal in a S and/or Se ambient to introduce the S and/or Se components to the layer.

The annealing serves to recrystallize the CZTSSe into a larger grain structure. According to an exemplary embodiment, the constituent components are heated (annealed) on a hot plate to a temperature of from about 500 degrees Celsius (° C.) to about 540° C. for a duration of from about 5 minutes to about 15 minutes.

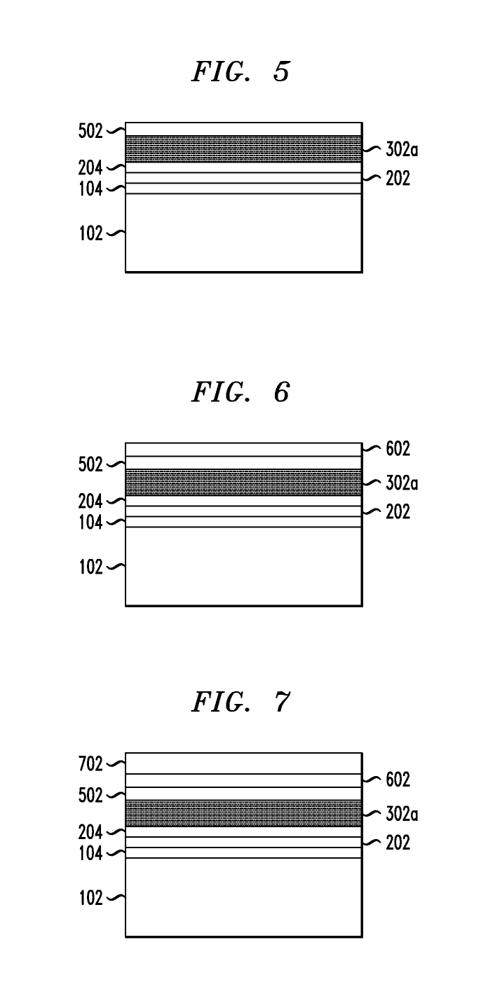

As shown in FIG. 5, a buffer layer 502 is then formed on CZTSSe absorber layer 302a. According to an exemplary embodiment, buffer layer 502 is made up of cadmium sulfide (CdS) and is deposited on CZTSSe absorber layer 302a using chemical bath deposition to a thickness of from about 60 nm to about 70 nm.

A transparent conductive electrode is then formed on buffer layer 502. The transparent conductive electrode is formed by first depositing a thin layer (e.g., having a thickness of from about 80 nm to about 100 nm) of intrinsic zinc oxide (ZnO) 602 on buffer layer 502. See FIG. 6. Next, a transparent conductive oxide layer 702 is deposited on intrinsic (ZnO) layer 602. See FIG. 7. According to an exemplary embodiment, transparent conductive oxide layer 702 is made up of Al-doped zinc oxide or indium-tin-oxide (ITO) and is deposited on ZnO layer 602 by sputtering.

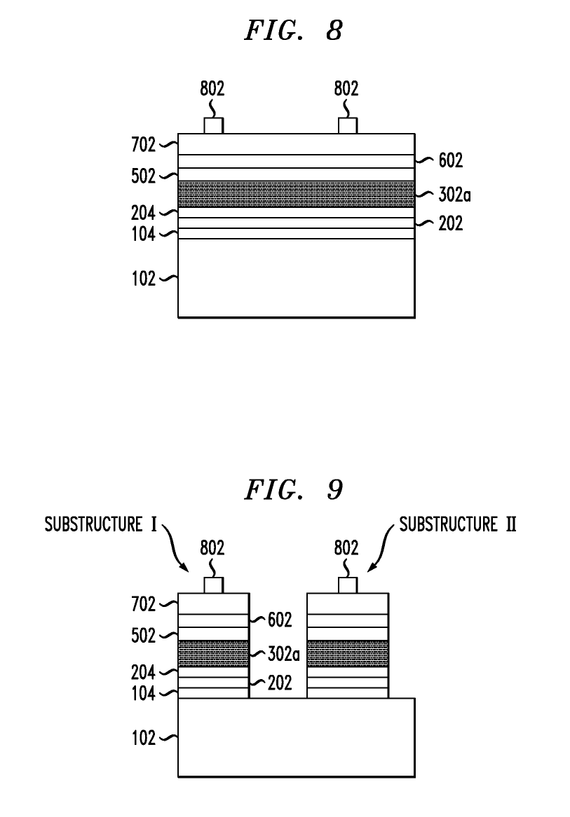

As shown in FIG. 8, a metal grid electrode 802 is then formed on the transparent conductive electrode. Metal grid electrode 802 can be formed from any suitable metal(s), such as nickel (Ni) and/or Al. The solar cell can then be divided into a number of isolated substructures. See FIG. 9. According to an exemplary embodiment, the substructures are cut with a laser or mechanical scriber. Solar cell fabrication techniques that may be implemented in conjunction with the present techniques are described, for example, in U.S. patent application Ser. No. ______, designated as Attorney Reference No. YOR920100576US1, entitled “Fabrication of CuZnSn(S,Se) Thin Film Solar Cell With Valve Controlled S and Se,” the contents of which are incorporated by reference herein.

As described above, the diffusion of Cu from the CZTSSe to (MoS)x and/or (MoSe)x can disturb the composition of the CZTSSe near the CZTSSe-Mo interface, which in turn can cause phase separation. See FIG. 10. FIG. 10 is a cross-sectional transmission electron microscopy (TEM) image 1000 of a CZTS layer-Mo interface showing the formation of a Mo(Cu,S) layer and the inhomogenous grains of CZTS near the interface.

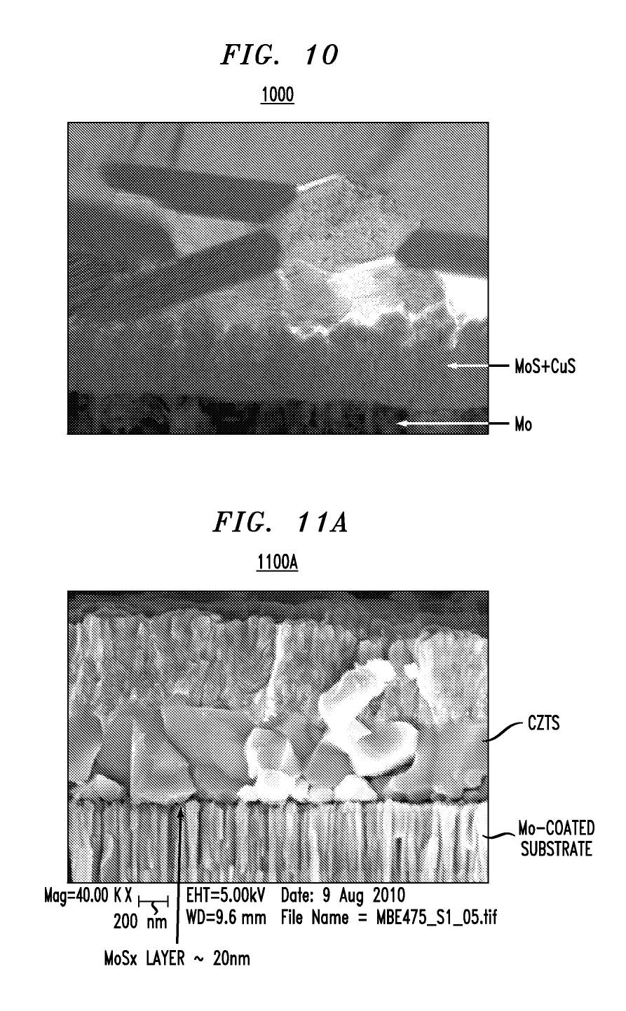

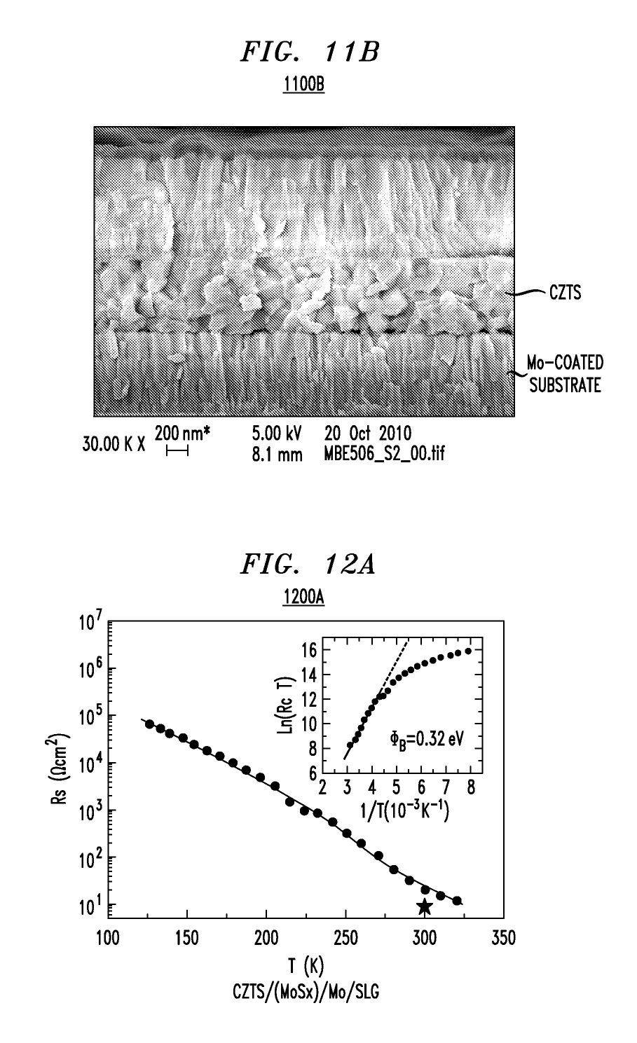

The present techniques are described further by way of reference to the following non-limiting examples. FIG. 11A is a scanning electron microscope (SEM) image 1100A of a solar cell fabricated using the present techniques. The solar cell in this example has a 3 nm thick TiN diffusion barrier. The diffusion barrier is between the CZTS and the Mo but its thickness, 3 nm, is below the resolution limit of SEM so it cannot be seen in the image. As indicated by the arrow in image 1100A, the thickness of a MoSx layer between the CZTS and the Mo-coated substrate was about 20 nm which is greatly reduced from a sample with no TiN diffusion barrier (not shown) which had a MoSx layer between the CZTS and the Mo-coated substrate with a thickness of about 130 nm. With increased thickness of the TiN layer (to 10 nm), the absence of any MoSx layer (at least within detection resolution of SEM) was confirmed. See SEM image 1100B in FIG. 11B. The diffusion barrier is between the CZTS and the Mo but its thickness, 10 nm, is below the resolution limit of SEM so it cannot be seen in the image. FIGS. 10 (described above), 11A and 11B show CZTS films (without Se) but this is only for exemplary purposes and as described herein the present techniques are applicable to CZTS, CZTSSe and CZTSe (without S).

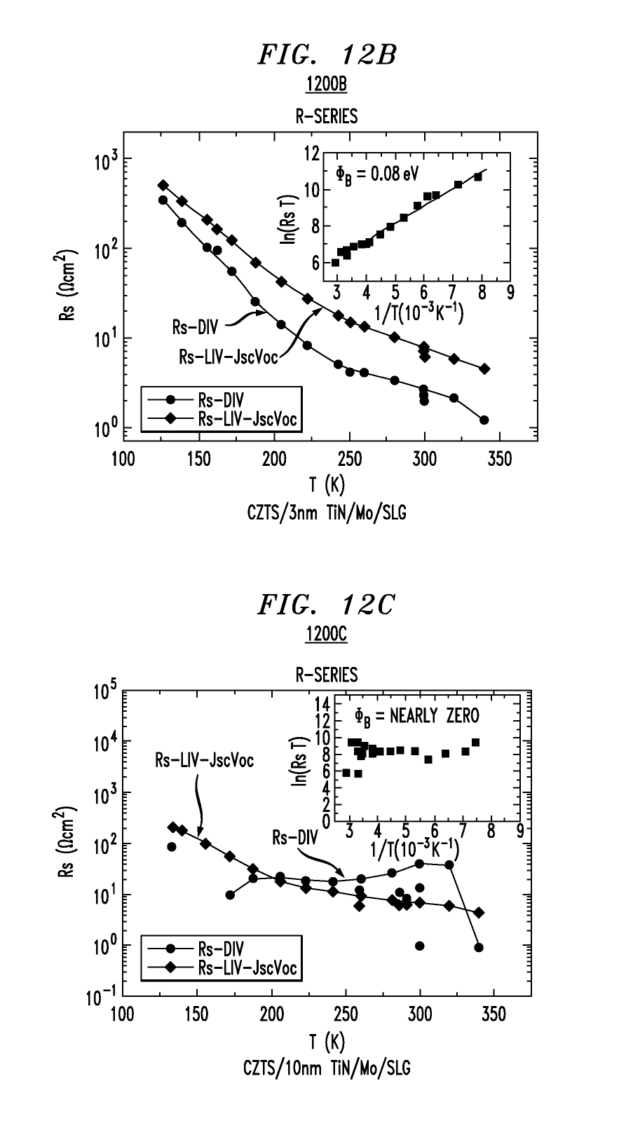

Immediate benefits of suppressing the formation of (MoS)x and/or (MoSe)x between the CZTSSe and the Mo-coated substrate (through the use of the present diffusion barrier layer) can be seen by reduced back-side contact barrier heights. See FIGS. 12A-C. FIGS. 12A-C are graphs 1200A-C illustrating temperature dependence of series resistance for three solar cell configurations, one with no TiN diffusion barrier, one with a 3 nm thick TiN diffusion barrier and one with a 10 nm thick diffusion barrier, respectively. In each of graphs 1200A-C temperature T (measured in degrees Kelvin) is plotted on the x-axis and series resistance Rs (Ω) per square centimeter (cm²) is plotted on the y-axis. The back-side contact barrier height can be extracted by examining the temperature (T) dependence of series resistance (Rs). The slope of ln(RsT) versus 1/T gives barrier height of the back-side contact, as show in the inset in each of graphs 1200A-C. This barrier height has a substantial impact on the transport/collection of photon-generated charged carriers. It can be seen from graphs 1200A-C that the barrier height reduces with increasing thickness of the TiN diffusion barrier. With a 10 nm TiN diffusion barrier, the back-side contact barrier height was completely removed which is very significant in optimizing CZTSSe-based thin film solar cell devices.

The mechanical stability of a CZTSSe absorber layer during high temperature annealing with a 1 μm thick Al layer between a TiN diffusion layer and a Mo-coated substrate was also tested. Specifically, while a CZTSSe layer of a stack having a 10 nm thick TiN diffusion layer between the Mo-coated substrate and the CZTS absorber layer delaminated during 540° C. annealing, the stack with 1 μm Al layer remained intact after the 540° C. annealing. The Al layer relieved stress, which otherwise would have been built in the CZTSSe layer from thermal mismatch, by undergoing plastic deformation. Use of the stress-relief layer permits the increase of CZTSSe film thickness without resulting in a mechanical failure during a high temperature annealing step.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method of fabricating a solar cell, comprising the steps of:
providing a substrate;
coating the substrate with a molybdenum layer;
depositing a stress-relief layer on the molybdenum layer;
coating the stress-relief layer with a diffusion barrier;
depositing absorber layer constituent components on the diffusion barrier, wherein the constituent components comprise one or more of sulfur and selenium;
annealing the constituent components to form an absorber layer on the diffusion barrier, wherein the stress-relief layer relieves thermal stress imposed on the absorber layer by the annealing step, and wherein the diffusion barrier blocks diffusion of the one or more of sulfur and selenium into the molybdenum layer during the annealing step;
forming a buffer layer on the absorber layer; and
forming a transparent conductive electrode on the buffer layer.

2. The method of claim 1, wherein the constituent components further comprise copper, and wherein the diffusion barrier blocks diffusion of the copper into the molybdenum layer during the annealing step.

3. The method of claim 1, wherein the substrate comprises a soda-lime glass substrate.

4. The method of claim 1, wherein the stress-relief layer has a thickness of from about 50 nanometers to about 1 micrometer.

5. The method of claim 1, wherein the stress-relief layer comprises a soft metal.

6. The method of claim 5, wherein the soft metal comprises one or more of aluminum, copper and silver.

7. The method of claim 1, wherein the stress-relief layer is deposited on the molybdenum-coated substrate using thermal evaporation or sputtering.

8. The method of claim 1, wherein the diffusion barrier has a thickness of from about 3 nanometers to about 50 nanometers.

9. The method of claim 1, wherein the diffusion barrier comprises one or more of titanium nitride, tantalum nitride and tantalum nitride silicide.

10. The method of claim 1, wherein the diffusion barrier is coated on the stress-relief layer using thermal evaporation with nitrogen plasma, sputtering, atomic layer deposition or chemical vapor deposition.

11. The method of claim 1, wherein the step of forming the absorber layer comprises the steps of:
depositing constituent components of the absorber layer on the diffusion barrier; and
annealing the constituent components to form the absorber layer on the diffusion barrier.

12. The method of claim 1, wherein the absorber layer comprises CuZnSn(S,Se).

13. The method of claim 12, wherein the constituent components comprise copper, zinc, tin, sulfur and selenium, and wherein the constituent components are deposited on the diffusion barrier using thermal evaporation.

14. The method of claim 1, wherein the buffer layer comprises cadmium sulfide.

15. The method of claim 1, wherein the buffer layer is formed using chemical bath deposition.

16. The method of claim 1, wherein the buffer layer is formed having a thickness of from about 60 nanometers to about 70 nanometers.

17. The method of claim 1, wherein the step of forming the transparent conductive electrode on the buffer layer comprises the steps of:
depositing a thin layer of intrinsic zinc oxide on the buffer layer; and
depositing a transparent conductive oxide layer on the intrinsic zinc oxide layer.

18. The method of claim 17, wherein the layer of intrinsic zinc oxide is deposited to a thickness of from about 80 nanometers to about 100 nanometers.

19. The method of claim 17, wherein the transparent conductive oxide layer is deposited by sputtering.

20. The method of claim 17, wherein the transparent conductive oxide layer comprises aluminum-doped zinc oxide or indium-tin-oxide.

21. The method of claim 1, further comprising the step of:
forming a metal grid electrode on the transparent conductive electrode.

22. The method of claim 1, further comprising the step of:
dividing the solar cell into a plurality of isolated substructures using a laser or mechanical scriber.

23. A solar cell, comprising:
a substrate;
a molybdenum layer coating the substrate;
a stress-relief layer disposed on the molybdenum layer;
a diffusion barrier coating the stress-relief layer;
an absorber layer formed on the diffusion barrier;
a buffer layer formed on the absorber layer; and
a transparent conductive electrode formed on the buffer layer.

24. The solar cell of claim 23, wherein the absorber layer comprises CuZnSn(S,Se).

25. The solar cell of claim 23, further comprising:
a metal grid electrode formed on the transparent conductive electrode.
